(19) United States
(12) Patent Application Publication
(10) Pub. No.: US 2024/0357877 A1
(43) Pub. Date: Oct. 24, 2024

(54) DISPLAY PANEL HAVING SHIELDING ELECTRODE AND DISPLAY DEVICE COMPRISING THE SAME

(71) Applicant: XIAMEN TIANMA DISPLAY TECHNOLOGY CO., LTD., Xiamen (CN)

(72) Inventor: Yongxiang LIN, Xiamen (CN)

(73) Assignee: XIAMEN TIANMA DISPLAY TECHNOLOGY CO., LTD., Xiamen (CN)

(21) Appl. No.: 18/762,651

(22) Filed: Jul. 3, 2024

(30) Foreign Application Priority Data
Oct. 23, 2023 (CN) 202311379190.8

(51) Int. Cl. H10K 59/126; H10K 59/131

(52) U.S. Cl. CPC H10K 59/126; H10K 59/131

(57) ABSTRACT

A display panel and a display device are provided. A part of a border area of the display panel surrounds an active area of the display panel. The border area includes a fan-out area located on a side of the active area and a bonding area located on a side of the fan-out area away from the active area. The display panel includes a substrate, a first metal layer arranged on a side of the substrate and including a signal wire, an organic layer arranged on a side of the first metal layer away from the substrate and including an opening defined in the border area, and a second metal layer including a shielding electrode arranged on a first section. The signal wire includes the first section located in the opening.

The present application claims priority to Chinese Patent Application No. 202311379190.8, titled “DISPLAY PANEL AND DISPLAY DEVICE”, filed on Oct. 23, 2023 with the China National Intellectual Property Administration, which is incorporated herein by reference in its entirety.

### FIELD

The present disclosure relates to the field of display, and in particular to a display panel and a display device.

### BACKGROUND

An organic light-emitting diode (OLED) display panel is a display device to actively emit light, has some advantages, such as self-luminous display, wide viewing angle, high contrast, full-color display, light weight, thin thickness, low power consumption and high response speed. In addition, the OLED display panel may achieve flexible display and is a display device with great development potential.

The OLED display panel is made of organic material. The organic material undergoes an irreversible photooxidation reaction in the presence of water vapor and oxygen. Therefore, the conventional OLED display panel is weak to isolate water and oxygen.

### SUMMARY

Based on this, a display panel and a display device are provided according to embodiments of the present disclosure, to improve the ability of the display panel to isolate water and oxygen, and to improve reliability and service life of the display panel.

A display panel is provided according to an embodiment of the present disclosure. At least a part of a border area of the display panel surrounds an active area of the display panel. The border area includes a fan-out area located on a side of the active area and a bonding area located on a side of the fan-out area away from the active area. The display panel includes a substrate, a first metal layer, an organic layer and a second metal layer.

The first metal layer is arranged on a side of the substrate, and the first metal layer includes a signal wire.

The organic layer is arranged on a side of the first metal layer away from the substrate, the organic layer includes an opening defined in a border area, and the signal wire includes a first section located in the opening.

The second metal layer includes a shielding electrode arranged on the first section, and a projection of the shielding electrode on the substrate overlaps at least partially with a projection of a side wall of the first section on the substrate.

In one embodiment, a display device including the display panel described in the embodiments are provided according to an embodiment of the present disclosure.

According to an embodiments of the present disclosure, the first metal layer is arranged on a side of the substrate and includes the signal wire, and the first section of the signal wire is located in the opening, and the first section is exposed outside. Further, the display panel according to the embodiment of the present disclosure is further provided with the second metal layer, the projection of the shielding electrode of the second metal layer on the substrate overlaps at least partially with the projection of the side wall of the first section on the substrate, and the shielding electrode can shield the side wall of the first section located in the opening. When an etching process is performed, the side wall of the first section shielded by the shielding electrode is not formed as the internal groove structure, and no organic material remains. In this way, along a direction of the bonding area to the fan-out area, at least part of the side wall of the first section does not include the organic material, and the erosion path of water vapor is blocked, avoiding defective pixels on the display panel, to improve the reliability and service life of the display panel.

### BRIEF DESCRIPTION OF THE DRAWINGS

FIG. 1 is a schematic plan view illustrating a display panel according to the conventional technology.

FIG. 2a is a schematic cross-sectional view illustrating that a side wall of a signal wire in a cavity does not react with etching fluid according to the conventional technology.

FIG. 2b is a schematic cross-sectional view illustrating that a side wall of a signal wire in a cavity reacts with etching fluid according to the conventional technology.

FIG. 3 is a schematic plan view illustrating a display panel according to an embodiment of the present disclosure.

FIG. 4 is a schematic cross-sectional view illustrating a structure of film layers of the display panel taken along a line A-A illustrated in FIG. 3.

FIG. 5 is a schematic cross-sectional view illustrating a structure of film layers of the display panel taken along a line B-B illustrated in FIG. 3.

FIG. 6 is an enlarged schematic diagram of a structure at M of the display panel illustrated in FIG. 3.

FIG. 7 is another enlarged schematic diagram of a structure at M of the display panel illustrated in FIG. 3.

FIG. 8 is another enlarged schematic diagram of a structure at M of the display panel illustrated in FIG. 3.

FIG. 9 is another enlarged schematic diagram of a structure at M of the display panel illustrated in FIG. 3.

FIG. 10 is another enlarged schematic diagram of a structure at M of the display panel illustrated in FIG. 3.

FIG. 11 is a schematic plan view illustrating a display panel according to another embodiment of the present disclosure.

FIG. 12 is an enlarged schematic diagram of a structure at N of the display panel illustrated in FIG. 11.

FIG. 13 is a schematic plan view illustrating a display panel according to another embodiment of the present disclosure.

FIG. 14 is an enlarged schematic diagram of a structure at P of the display panel illustrated in FIG. 13.

### DETAILED DESCRIPTION

In order to make the embodiments of the present disclosure more apparent and understandable, specific implementations of the present disclosure are described in detail below in conjunction with the drawings. Specific details are described in the following description and the present disclosure can be understood completely. However, the present disclosure may be implemented in many other ways different from those described herein, and similar improvements may be made without departing from the embodiments of the present disclosure. Therefore, the present disclosure is not limited by the embodiments described hereinafter.

In the description of the present disclosure, it should be understood that the orientation or positional relationships indicated by terms such as “center”, “longitudinal”, “lateral”, “length”, “width”, “thickness”, “up”, “down”, “front”, “rear”, “left”, “right”, “vertical”, “horizontal”, “top”, “bottom”, “inner”, “outer”, “clockwise”, “anticlockwise”, “axial”, “radial”, “circumferential” and the like are based on the orientation or positional relationships shown in the drawings, and are merely for the convenience of describing the present disclosure and the simplification of the description, and do not indicate or imply that the apparatus or component referred must be in a particular orientation, or be constructed and operated in a particular orientation, and therefore should not be construed as a limitation to the present disclosure.

Furthermore, in a case that the terms “first” and “second” are used, which is merely for purpose of description, and should not be construed as indicating or implying relative importance or implying the number of the indicated features. Therefore, features defined with “first” or “second” may include at least one of the features explicitly or implicitly. In the description of the present disclosure, the term “multiple”, “plurality of” means at least two, such as two, or three, unless clearly and specific defined otherwise.

In the present disclosure, unless clearly defined and limited otherwise, terms “install”, “link”, “connect” and “fix” should be understood in a broad sense. For example, “connection” may be a fixed connection, a detachable connection, or connection as an integral; “connection” may be a mechanical connection or an electrical connection; “connection” may be a direct connection, an indirect connection through an intermediate medium, or internal communication between two components or interaction relationship between two components, unless clearly limited otherwise.

In the present disclosure, unless clearly defined and limited otherwise, similar descriptions of a first feature “above” or “below” a second feature may mean that the first and second features are in direct contact, or that the first and second features are in indirect contact through an intermediate medium. Furthermore, the first feature being “above”, “over” and “on” the second feature indicates that the first feature is directly above and diagonally above the second feature, or simply indicates that the first feature is higher than the second feature in horizontal height. The first feature being “below”, “under” and “down” the second feature indicates that the first feature is directly below and diagonally below the second feature, or simply indicates that the first feature is lower than the second feature in horizontal height.

It should be noted that when an element is referred to as being “fixed on” or “arranged on” another element, the element may be directly on the another element or there may be an intermediate element. When an element is referred to as being “connected to” another element, the element may be directly connected to the another element or there may be an intermediate element. The terms “vertical”, “horizontal”, “up”, “down”, “left”, “right” and similar expressions are used herein only for purpose of description and not intended to represent the only embodiment.

As described in the background, the OLED display panel is made of organic material. The organic material undergoes an irreversible photooxidation reaction in the presence of water vapor and oxygen. Therefore, the conventional OLED display panel is weak to isolate water and oxygen.

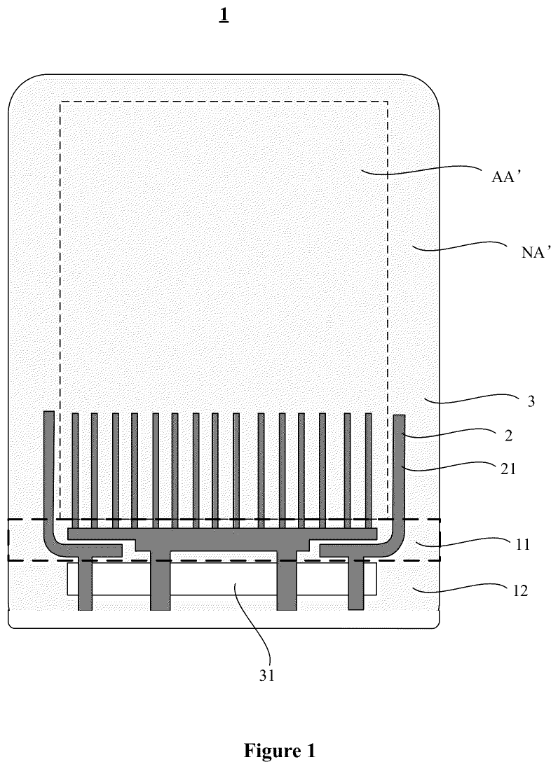

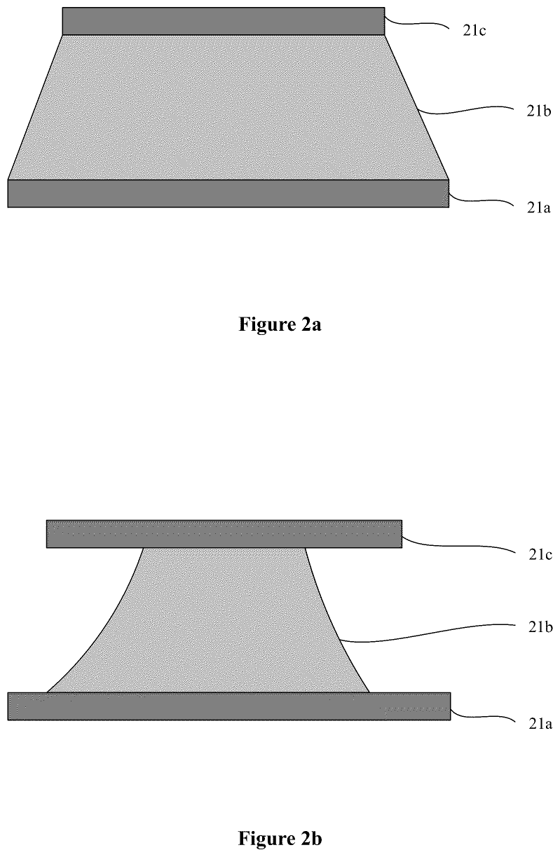

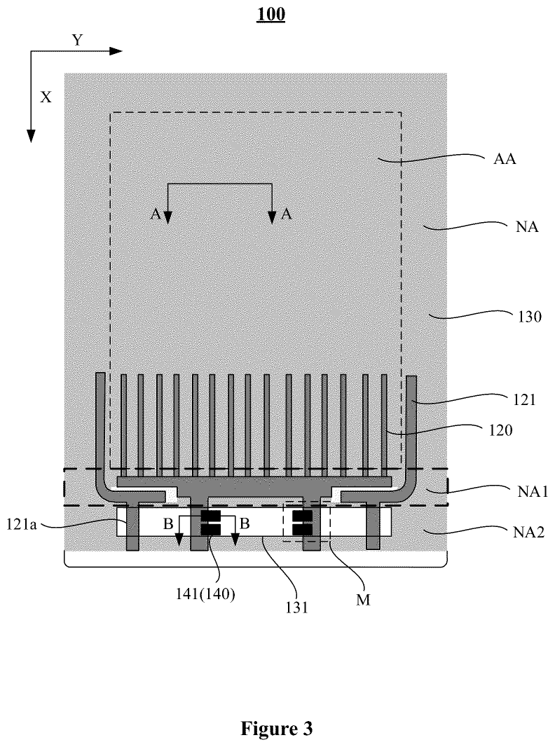

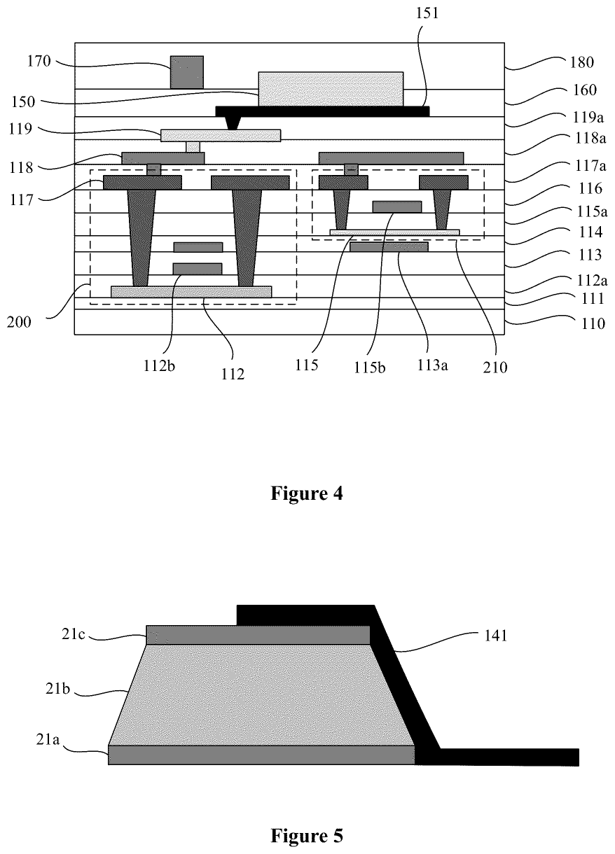

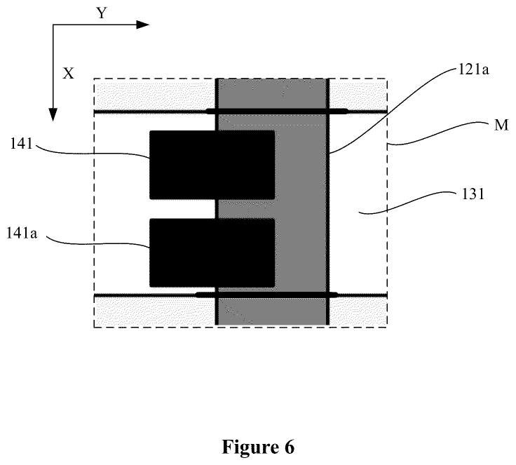

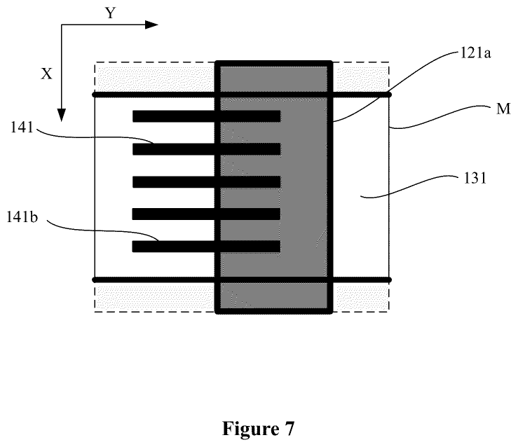

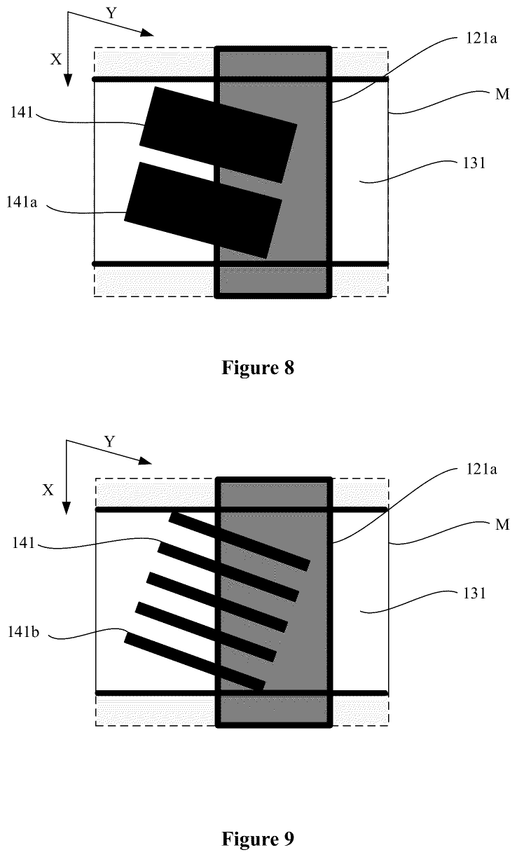

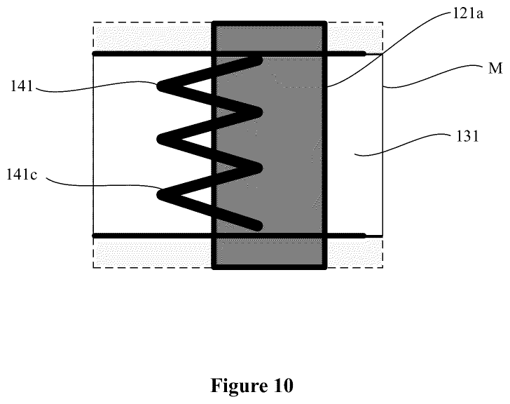

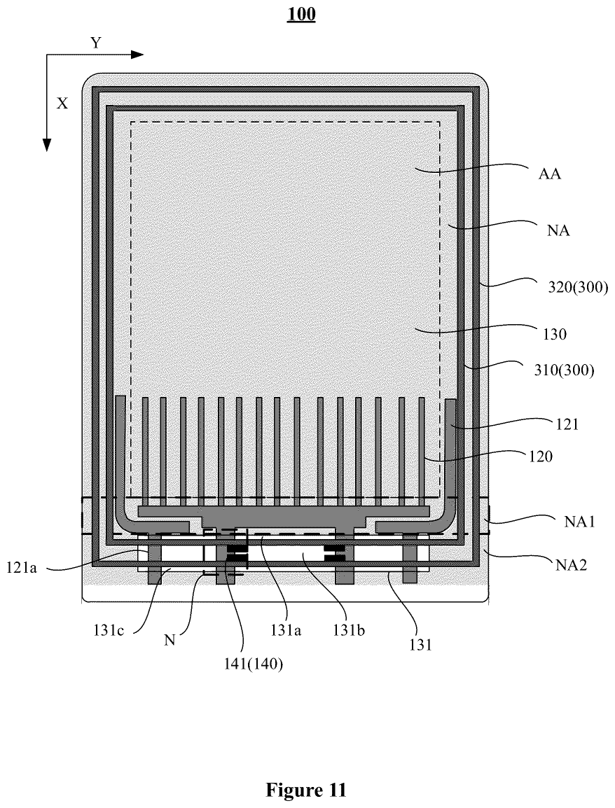

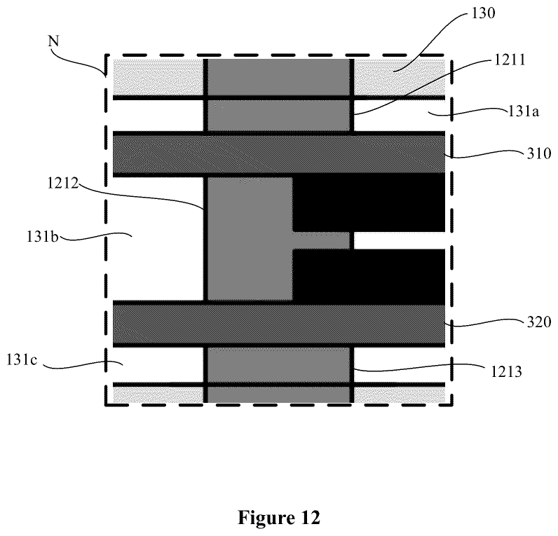

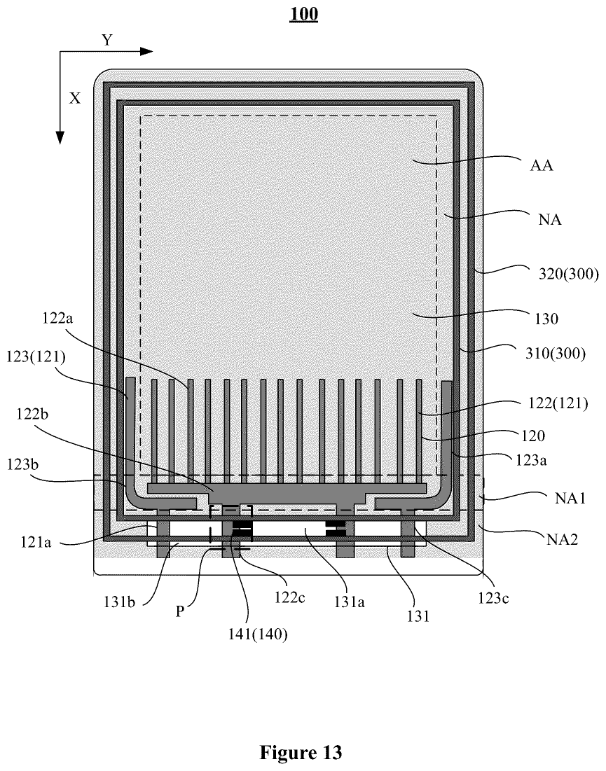

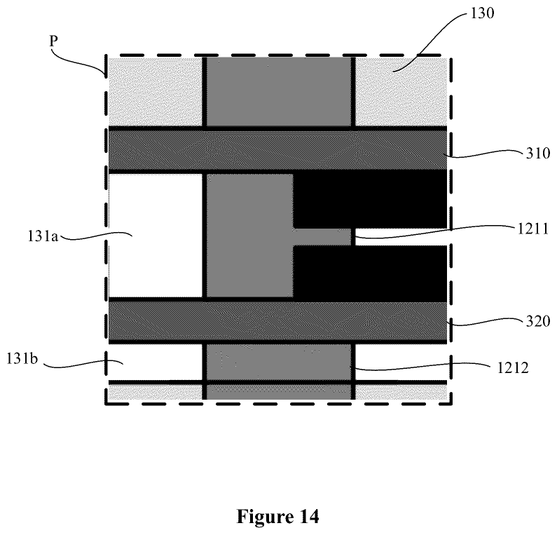

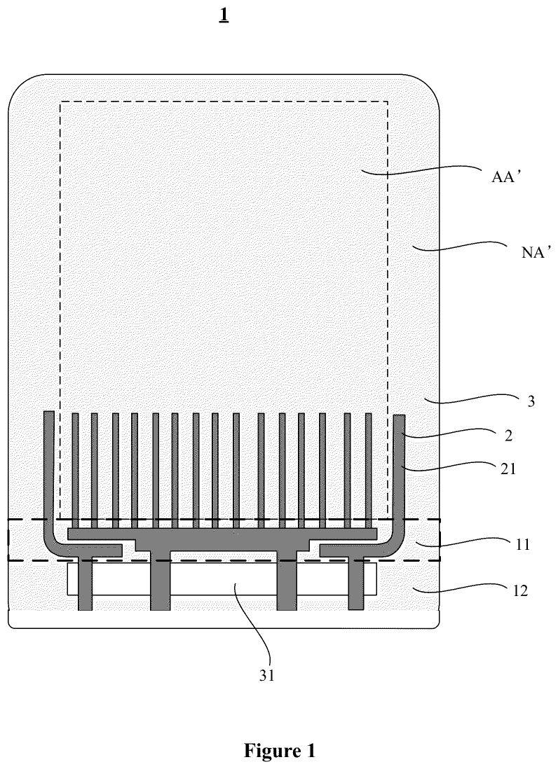

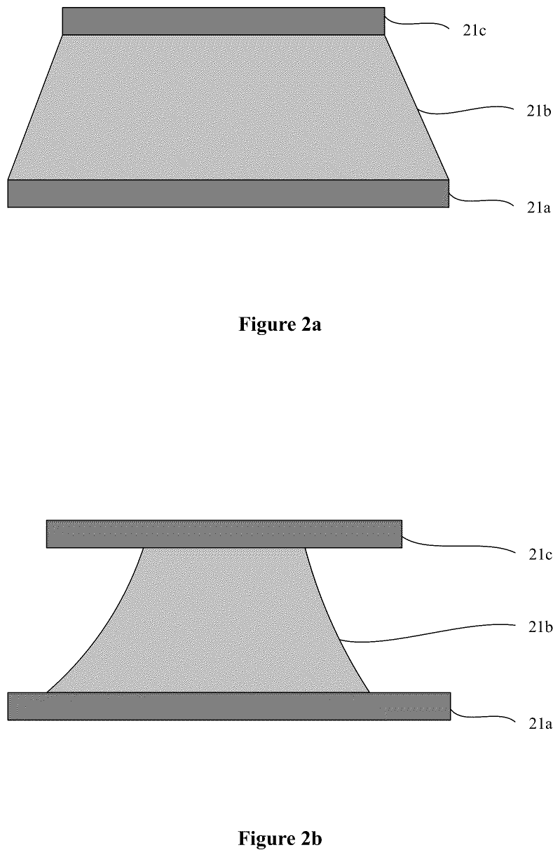

As shown in FIG. 1, FIG. 1 is a schematic structural diagram illustrating film layers formed by a metal layer and an organic layer of a display panel that are stacked according to the conventional technology. A border area NA′ of a display panel 1 surrounds an active area AA′ of the display panel 1. The border area NA′ includes a fan-out area 11 located on a side of the active area AA′ and a bonding area 12. The display panel 1 includes a substrate and a metal layer 2 located on a side of the substrate and an organic layer 3. The metal layer 2 includes a signal wire 21. The signal wire 21 may provide a power supply voltage signal such as a PVDD signal and a PVEE signal. The organic layer 3 is arranged on the metal layer 2, and a cavity 31 is defined on the organic layer 3. In this way, the signal wire 21 is partially exposed by the cavity 31. Since the organic layer 3 has a property of water absorption, the cavity 31 can prevent external water vapor from entering the active area AA′ of the display panel 1 along the organic layer 3. In general, the cavity 31 surrounds the active area AA′. FIG. 1 only exemplarily illustrates a part of the cavity 31. Further, in order to reduce an impedance of the signal wire 21 and improve electrical conductivity of the signal wire 21, the signal wire 21 is in a stacked structure formed by a titanium layer 21a, an aluminum layer 21b and a titanium layer 21c. When anodic etching is performed on an OLED, etching fluid reacts with the aluminum layer 21b in a side wall of the signal wire 21 in the cavity 31. As shown in FIG. 2a and FIG. 2b, FIG. 2a is a schematic cross-sectional view illustrating that the side wall of the signal wire 21 in the cavity 31 does not react with the etching fluid according to the conventional technology, and FIG. 2b is a schematic cross-sectional view illustrating that the side wall of the signal wire 21 in the cavity 31 reacts with the etching fluid according to the conventional technology. It can be seen from the comparison that the side wall of the signal wire 21 is corroded by the etching fluid to form an internal groove structure. In this way, if an organic structure such as a pixel definition layer and a support column above the anode is made, the organic material remains in the internal groove structure of the signal wire 21. As a result, in a direction from the bonding area 12 to the active area AA′, the side wall of the signal wire 21 is formed as an erosion path of water vapor, and finally defective pixels appear on the active area AA′ of the display panel 1, which is not conducive to the improvement of the reliability and service life of the display panel 1.

In one embodiment, a display panel is provided according to an embodiment of the present disclosure. At least a part of a border area of the display panel surrounds an active area of the display panel. The border area includes a fan-out area located on a side of the active area and a bonding area located on a side of the fan-out area away from the active area. The display panel includes a substrate, a first metal layer, an organic layer and a second metal layer. The first metal layer is arranged on a side of the substrate, and the first metal layer includes a signal wire. The organic layer is arranged on a side of the first metal layer away from the substrate. The organic layer includes an opening defined in the border area. The signal wire includes a first section located in the opening. The second metal layer includes a shielding electrode arranged on the first section. A projection of the shielding electrode on the substrate overlaps at least partially with a projection of a side wall of the first section on the substrate. According to the embodiment of the present disclosure, the first metal layer is arranged on the side of the substrate, the first metal layer includes the signal wire, and the first section of the signal wire is located in the opening, and the first section is exposed outside. Further, the display panel according to the embodiment of the present disclosure is further provided with the second metal layer, and the projection of the shielding electrode of the second metal layer on the substrate overlaps at least partially with the projection of the side wall of the first section on the substrate, and the shielding electrode can shield the side wall of the first section located in the opening. When an etching process is performed, the side wall of the first section shielded by the shielding electrode is not formed as the internal groove structure, and no organic material remains. In this way, along the direction from the bonding area to the fan-out area, at least part of the side wall of the first section does not include the organic material, and the erosion path of water vapor is blocked, avoiding defective pixels on the display panel, to improve the reliability and service life of the display panel.

The embodiments of the present disclosure are described clearly and completely in conjunction with the drawings in the embodiments of the present disclosure hereinafter.

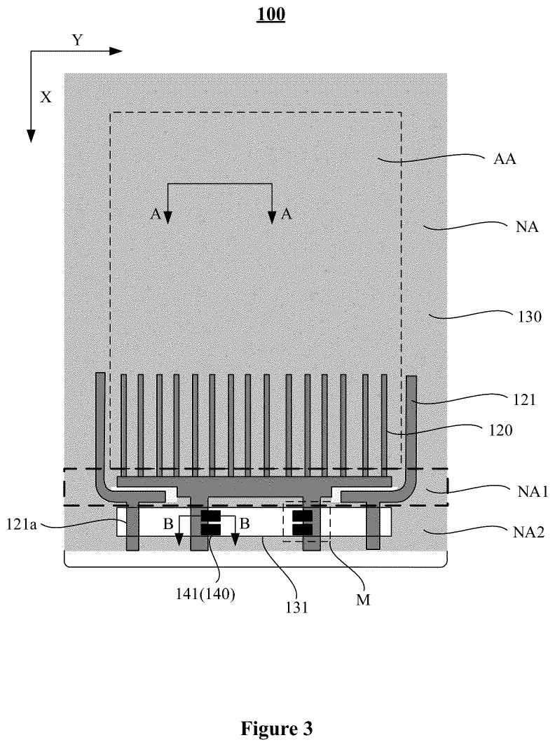

A shown in FIG. 3 to FIG. 5, a display panel 100 is provided according to an embodiment of the present disclosure. At least a part of a border area NA of the display panel 100 surrounds an active area AA of the display panel 100. The border area NA includes a fan-out area NA1 located at a side of the active area AA and a bonding area NA2 located at a side of the fan-out area NA1 away from the active area AA. The display panel 100 includes a substrate 110, a first metal layer 120, an organic layer 130, and a second metal layer 140. The first metal layer 120 is arranged on a side of the substrate 110. The first metal layer 120 includes a signal wire 121. The organic layer 130 is arranged on a side of the first metal layer 120 away from the substrate 110. The organic layer 130 includes an opening 131 defined in the border area NA. The signal wire 121 includes a first section 121a located in the opening 131. The second metal layer 140 includes a shielding electrode 141 arranged on the first section 121a. A projection of the shielding electrode 141 on the substrate 110 overlaps at least partially with a projection of a side wall of the first section 121a on the substrate 110.

According to the embodiment of the present disclosure, at least a part of the border area NA of the display panel 100 surrounds the active area AA of the display panel 100. The active area AA includes multiple sub-pixels. Each of the sub-pixels includes a pixel driving circuit and a light-emitting unit electrically connected to the pixel driving circuit. The border area NA includes a top border, a bottom border, a left border, and a right border of the display panel 100. It should be understood that in some embodiments, the border area NA may be located on one or more sides of the active area AA, which is not limited in the embodiments of the present disclosure. The border area NA surrounds the active area AA, and is provided with various driving circuits such as multiple signal wires and an IC chip. The IC chip is arranged in the bonding area NA2 in the border area NA.

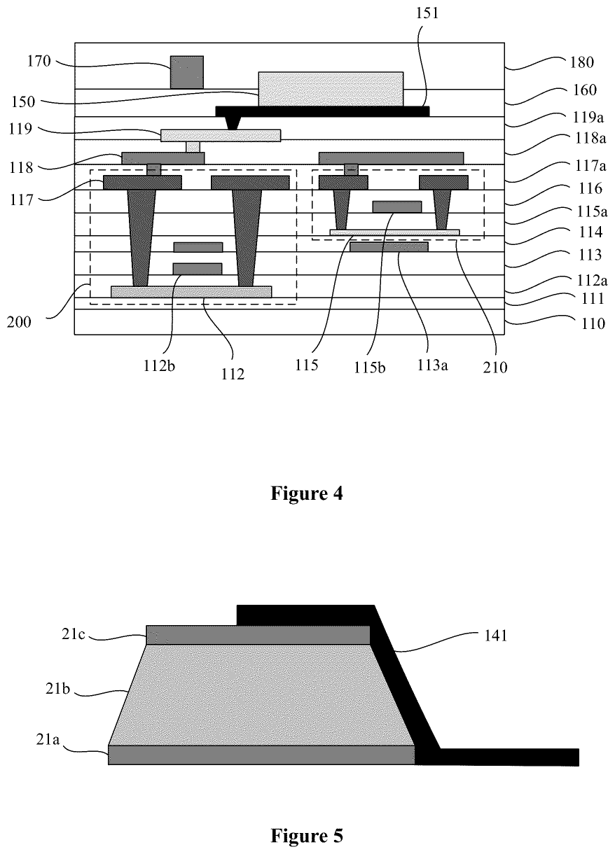

According to the embodiment of the present disclosure, the display panel 100 includes the substrate 110, the first metal layer 120, the organic layer 130 and the second metal layer 140. In order to facilitate the description of a structure of film layers of the display panel 100, FIG. 4 is a schematic cross-sectional view that exemplarily illustrates the active area AA of the display panel 100 taken along a line A-A according to the embodiment of the present disclosure. The display panel 100 is a display panel based on low-temperature polycrystalline silicon (LTPO) technology, that is, the display panel 100 includes a low-temperature polycrystalline silicon thin-film transistor 200 and an oxide thin-film transistor 210, and the display panel 100 combines the advantages of low-temperature polycrystalline silicon and oxide, improving the performance of the display panel 100.

In one embodiment, the display panel 100 includes the substrate 110, a buffer layer 111, a first semiconductor layer 112, a first gate insulating layer 112a, a first gate layer 112b, a capacitor insulating layer 113, a capacitor metal layer 113a, a first interlayer insulating layer 114, a second semiconductor layer 115, a second gate insulating layer 115a, a second gate layer 115b, a second interlayer insulating layer 116, a source-drain metal layer 117, a first planarization layer 117a, a first transfer metal layer 118, a second planarization layer 118a, a second transfer metal layer 119, a third planarization layer 119a, a light-emitting unit 150, a pixel definition layer 160, a support layer 170 and a package layer 180 that are stacked in sequence.

The substrate 110 may be a flexible substrate or a rigid substrate, which is not limited in the present disclosure. The light-emitting unit 150 includes a first electrode layer 151, a light-emitting material layer and a second electrode layer that are arranged on the pixel definition layer 160 in sequence. The light-emitting material layer is driven by the first electrode layer 151 and the second electrode layer to emit visible light by excitation. The light-emitting material layer may include one or more layers of an election transporting layer (ETL), an election injection layer (EIL), and a hole transporting layer (HTL) and a hole injection layer (HIL). The support layer 170 includes multiple support columns for supporting a mask plate in the evaporation process. The package layer 180 is arranged on a side of the light-emitting unit 150 away from the substrate 110. The package layer 180 is configured to isolate water and oxygen, to prevent the erosion of the light-emitting unit 150 by water and oxygen. In an embodiment, the package layer 180 may include a first inorganic layer, an organic package layer and a second inorganic layer that are stacked in sequence. The first inorganic layer and the second inorganic layer are configured to isolate external water and oxygen, and the organic package layer is configured to perform stress release and planarization within the film layers.

The first metal layer 120, the organic layer 130 and the second metal layer 140 according to the embodiment of the present disclosure are illustrated in conjunction with FIG. 4.

In the present disclosure, the first metal layer 120 is arranged on a side of the substrate 110. The first metal layer 120 includes a signal wire 121. The signal wire 121 may be, for example, a first power supply voltage signal wire or a second power supply voltage signal wire. As shown in FIG. 2a, in order to reduce the impedance of the signal wire 121 and improve the electrical conductivity of the signal wire 121, the first metal layer 120 is in a stacked structure formed by a titanium layer 21a, an aluminum layer 21b and a titanium layer 21c. As shown in FIG. 4, the first metal layer 120 may be one of the first transfer metal layer 118 and the second transfer metal layer 119. In an embodiment, the first metal layer 120 is the second transfer metal layer 119. That is, the signal wire 121 is fabricated by using the second transfer metal layer 119. The reason is that the signal wire 121 is electrically connected to the electrode layers of the light-emitting unit 150, and the second transfer metal layer 119 is relatively close to the electrode layers of the light-emitting unit 150, and thus the signal wire 121 is fabricated on the second transfer metal layer 119, facilitating the electrical connection between the signal wire 121 and the light-emitting unit 150, and reducing the impedance of the signal wire 21 during electrical connection.

The organic layer 130 may be one of the second planarization layer 118a and the third planarization layer 119a. In a case that the first metal layer 120 is the second transfer metal layer 119, the organic layer 130 is the third planarization layer 119a. The organic layer 130 is configured to planarize the display panel 100. Since the organic layer 130 has a property of water absorption, the opening 131 defined in the organic layer 130 can prevent water vapor from entering the active area AA of the display panel 100 along the organic layer 130. In general, an area where the opening 131 is located is referred to as an organic layer clearance area.

It should be noted that FIG. 3 only exemplarily illustrates the opening 131 of the organic layer 130 located on a side of the border area NA. In practice, the opening 131 may be annular and surrounds the active area AA. In an embodiment, the opening 131 may be discontinuous, that is, the opening 131 surrounds the active area AA and is discontinuous. For example, the organic layer 130 includes multiple openings 131 surrounding the active area AA, and any two adjacent openings 131 are spaced apart. In an embodiment, the multiple openings 131 may be the same or different in width, and the structure (such as a position, shape, and size) of the openings 131 is not limited in the present disclosure.

The second metal layer 140 includes the shielding electrode 141 arranged on the first section 121a. That is, the second metal layer 140 is located on a side of the first metal layer 120 away from the substrate 110. As shown in FIG. 4, for example, the second metal layer 140 and the first electrode layer 151 of the light-emitting unit 150 may be arranged in the same layer. Further, the shielding electrode 141 is located in the opening 131, and the projection of the shielding electrode 141 on the substrate 110 overlaps at least partially with the projection of the side wall of the first section 121a on the substrate 110. In this way, as shown in FIG. 5, the shielding electrode 141 can shield the side wall of the first metal layer 120.

It should be noted that the first metal layer 120, the organic layer 130 and the second metal layer 140 are described above by taking the display panel 100 based on the LTPO technology shown in FIG. 4 as an example. The present disclosure may further be applied to a display panel 100 based on non-LTPO technology. The structure of the film layers is implemented according to the conventional technology, which is not repeated herein. In a case that the display panel 100 is the display panel based on the non-LTPO technology, the first metal layer 120 may be a metal layer closest to the first electrode layer 151 of the light-emitting unit 150, the organic layer 130 may be a film layer for planarizing the first metal layer 120, and the second metal layer 140 may be a metal layer located on a side of the first metal layer 120 away from the substrate 110.

According to the embodiment of the present disclosure, the first metal layer 120 is arranged on a side of the substrate 110, and the first metal layer 120 includes the signal wire 121, the first section 121a of the signal wire 121 is located in the opening 131, and the first section 121a is exposed outside. Further, the display panel according to the embodiment of the present disclosure is further provided with the second metal layer 140, the projection of the shielding electrode 141 of the second metal layer 140 on the substrate 110 overlaps at least partially with the projection of the side wall of the first section 121a on the substrate 110, and the shielding electrode 141 can shield the side wall of the first section 121a located in the opening 131. When an etching process is performed, the side wall of the first section 121a shielded by the shielding electrode 141 is not formed as an internal groove structure, and no organic material remains. In this way, along a direction from the bonding area NA2 to the fan-out area NA1, at least part of the side wall of the first section 121a does not include the organic material, and the erosion path of water vapor is blocked, avoiding defective pixels on the display panel 100, to improve the reliability and service life of the display panel 100.

FIG. 3 only exemplarily illustrates that the shielding electrode 141 covers one side wall of the first section 121a. It should be noted that in FIG. 3, two side walls of the first section 121a located in the opening 131 are exposed by the opening 131. Therefore, the shielding electrode 141 covers two side walls of the first section 121a in a width direction of the first section 121a. The shielding electrode 141 may be flexibly set on the exposure of the side wall of the first section 121a located in the opening 131, as long as the shielding electrode 141 at least partially covers the exposed side wall of the first section 121a along an extension direction of the first section 121a.

In some embodiments, as shown in FIG. 3, the first section 121a extends along a first direction X, and the shielding electrode 141 extends along a second direction Y. The first direction X is a direction from the fan-out area NA1 to the bonding area NA2, and the second direction Y is not parallel with the first direction X. In this embodiment, the first section 121a extends along the first direction X, and the first direction X is the direction from the fan-out area NA1 to the bonding area NA2. The first section 121a is exposed by the opening 131. The shielding electrode 141 extends along the second direction Y, and the second direction Y is not parallel with the first direction X. In this way, the shielding electrode 141 can better shield the side wall of the first section 121a, to improve the reliability and service life of the display panel 100.

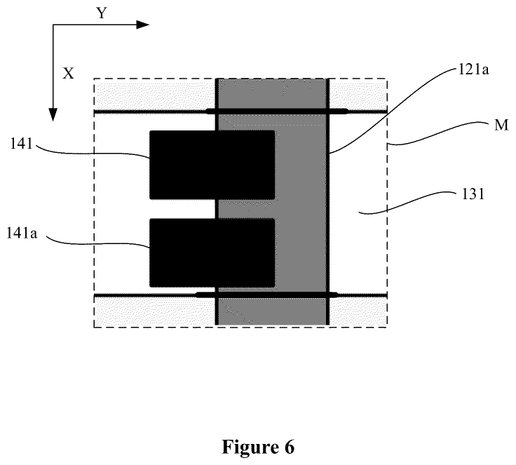

In some embodiments, as shown in FIG. 6, the shielding electrode 141 includes at least one electrode block 141a. In this way, the arrangement of the at least one electrode block 141a can shield the side wall of the first section 121a. The side wall of the first section 121a shielded by the shielding electrode 141 is not formed as the internal groove structure, and no organic material remains. In this way, along the first direction X, at least part of the side wall of the first section 121a does not include the organic material, and the erosion path of water vapor along the first direction X is blocked, avoiding defective pixels on the display panel 100, to improve the reliability and the service life of the display panel 100.

In an embodiment, as shown in FIG. 6, a quantity of the at least one electrode block 141a is two, and two electrode blocks 141a are spaced apart. In this way, even if one of the two electrode blocks 141a incompletely shields the side wall of the first section 121a, to cause a part of the side wall of the first section 121a that is not shielded to be formed as the internal groove structure, the erosion path of water vapor formed along the first direction X is also blocked under the shielding of the other electrode block 141a. In other words, only if each electrode block 141a fails to shield the side wall of the first section 121a, the erosion path of water vapor formed along the first direction X is unblocked, which is beneficial to improving the reliability of shielding the side wall of the first section 121a located in the opening 131 by the shielding electrode 141, to improve the reliability and service life of the display panel 100.

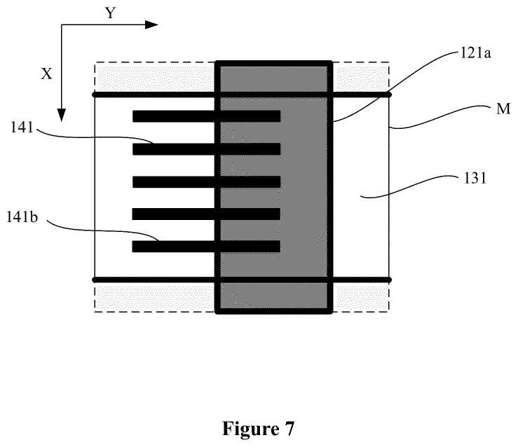

In some embodiments, as shown in FIG. 7, the shielding electrode 141 includes multiple metal wires 141b arranged in parallel. In this way, on the one hand, the area of the shielding electrode 141 is reduced, reducing fabrication cost. On the other hand, the shielding electrode 141 includes multiple metal wires 141b, and thus the erosion path of water vapor formed along the first direction X is unblocked only if each metal wire 141b fails to shield the side wall of the first section 121a, which is beneficial to improving the reliability of shielding the side wall of the first section 121a located in the opening 131 by the shielding electrode 141, to improve the reliability and the service life of the display panel 100.

In some embodiments, as shown in FIG. 6 and FIG. 7, the first direction X is perpendicular to the second direction Y. That is, the extension direction of the first section 121a is perpendicular to an extension direction of the shielding electrode 141, to improve the convenience of fabricating the first section 121a and the shielding electrode 141.

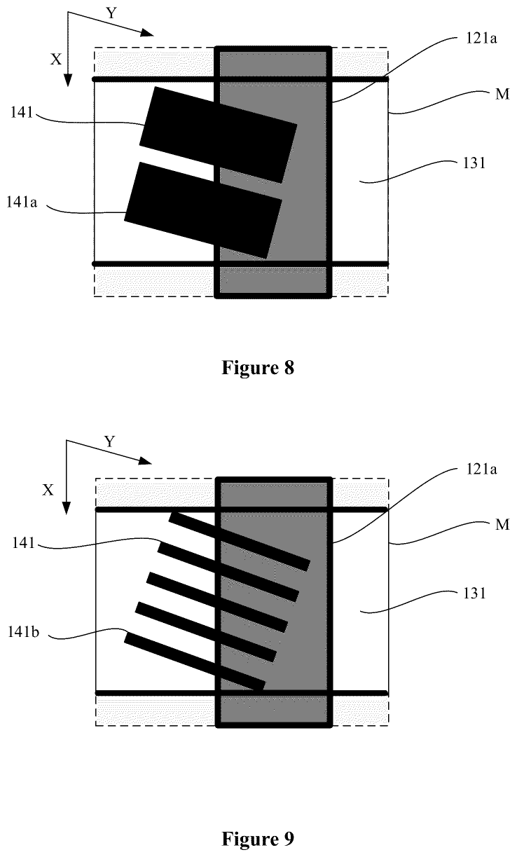

In some embodiments, as shown in FIG. 8 and FIG. 9, at an angle between the first direction X and the second direction Y is predetermined. That is, the extension direction of the first section 121a is not parallel with and also not perpendicular to the extension direction of the shielding electrode 141. In this way, a shielded width of the first section 121a by the shielding electrode 141 is increased, which is beneficial to improving the reliability of shielding the side wall of the first section 121a located in the opening 131 by the shielding electrode 141, to improve the reliability and the service life of the display panel 100.

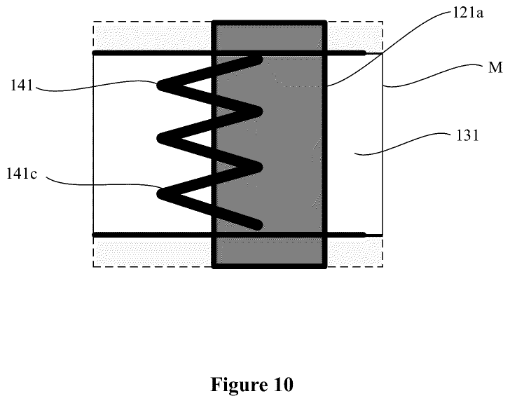

In some embodiments, as shown in FIG. 10, the shielding electrode 141 includes a metal wire 141c zigzagging in a length direction of the first section 121a. In this way, on the one hand, the shielding electrode 141 is in contact with the side wall of the first section 121a at multiple points, which is beneficial to improving the reliability of shielding the side wall of the first section 121a located in the opening 131 by the shielding electrode 141, to improve the reliability and the service life of the display panel 100. On the other hand, a shielded width of the first section 121a by the shielding electrode 141 is increased, which is beneficial to further improving the reliability and the service life of the display panel 100.

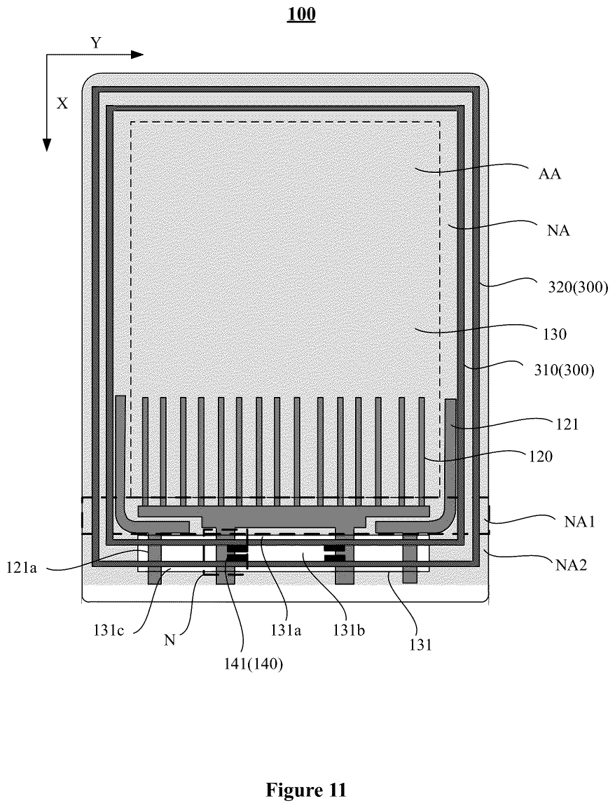

In some embodiments, as shown in FIG. 11, the display panel 100 further includes a retaining wall structure 300 arranged on the first metal layer 120. The retaining wall structure 300 is arranged in the border area NA and surrounds the active area AA. The projection of the first section 121a on the substrate 110 overlaps partially with a projection of the retaining wall structure 300 on the substrate 110. The package layer 180 is configured to package the light-emitting unit 150 on the display panel 100, and the package layer 180 generally includes an organic package layer. In this way, the organic package layer planarizes the display panel 100, and improves the effect of isolating water vapor. Therefore, the arrangement of the retaining wall structure 300 may block the organic material of the package layer 180, to avoid the formation of the erosion path of water and oxygen due to the organic material spilling into the border area NA, which is beneficial to further improving the service life and reliability of the display panel 100. Furthermore, the retaining wall structure 300 is arranged on the first metal layer 120, and the projection of the first section 121a on the substrate 110 overlaps partially with the projection of the retaining wall structure 300 on the substrate 110. Therefore, the retaining wall structure 300 can shield the surface and the side wall of the first section 121a, and the shielding electrode 141 is arranged on a part of the first section 121a located in the opening 131 that is not covered by the retaining wall structure 300, which is beneficial to improving the convenience of the arrangement of the shielding electrode 141, and reducing the area of the shielding electrode 141.

In some embodiments, as shown in FIG. 11, the retaining wall structure 300 includes a first retaining wall 310 and a second retaining wall 320, the second retaining wall 320 is arranged on a side of the first retaining wall 310 away from the active area AA, and at least a part of an orthographic projection of the opening 131 on the substrate 110 is located between the first retaining wall 310 and the second retaining wall 320.

In this embodiment, the retaining wall structure 300 includes the first retaining wall 310 and the second retaining wall 320. The arrangement of the two retaining walls can further improve the ability of the display panel 100 to isolate water and oxygen. Further, at least a part of the orthographic projection of the opening 131 on the substrate 110 is located between the first retaining wall 310 and the second retaining wall 320. That is, the orthographic projection of the opening 131 on the substrate 110 may be completely located between the first retaining wall 310 and the second retaining wall 320. In one embodiment, a part of the orthographic projection of the opening 131 on the substrate 110 is located between the first retaining wall 310 and the second retaining wall 320, and the other part of the orthographic projection is located on a side of the first retaining wall 310 away from the second retaining wall 320. In one embodiment, a part of the orthographic projection of the opening 131 on the substrate 110 is located between the first retaining wall 310 and the second retaining wall 320, and the other part of the orthographic projection is located on a side of the second retaining wall 320 away from the first retaining wall 310. In one embodiment, a first part of the orthographic projection of the opening 131 on the substrate 110 is located between the first retaining wall 310 and the second retaining wall 320, a second part of the orthographic projection is located on the side of the first retaining wall 310 away from the second retaining wall 320, and a third part of the orthographic projection is located on the side of the second retaining wall 320 away from the first retaining wall 310. That is, the opening 131 may be divided into one area, two areas or three areas in the extension direction of the first section 121a, that is, the first direction X.

In an embodiment, as shown in FIG. 11, the opening 131 includes a first sub-opening 131a located on a side of the first retaining wall 310 away from the second retaining wall 320, a second sub-opening 131b located between the first retaining wall 310 and the second retaining wall 320, and a third sub-opening 131c located on a side of the second retaining wall 320 away from the first retaining wall 310. In other words, along the extension direction of the first section 121a, that is, the first direction X, the opening 131 is divided into three sub-areas, and all the three sub-areas are organic layer clearance areas.

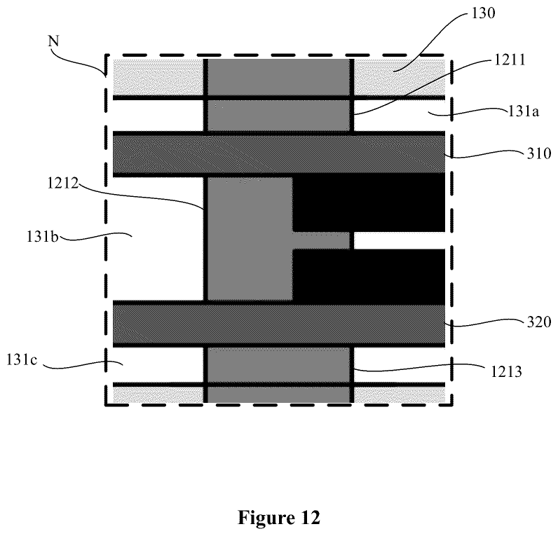

Further, in some embodiments, as shown in FIG. 12, the first section 121a includes a first sub-section 1211 located on the side of the first retaining wall 310 away from the second retaining wall 320, a second sub-section 1212 located between the first retaining wall 310 and the second retaining wall 320, and a third sub-section 1213 located on the side of the second retaining wall 320 away from the first retaining wall 310. In other words, in a case that the opening 131 is divided into three sub-areas: the first sub-opening 131a, the second sub-opening 131b and the third sub-opening 131c, the first section 121a is also divided into three sub-sections except a part of the first section 121a covered by the first retaining wall 310 and the second retaining wall 320. In one embodiment, the first section 121a includes the first sub-section 1211, the second sub-section 1212 and the third sub-section 1213. In this way, the first sub-section 1211, the second sub-section 1212 and the third sub-section 1213 are exposed outside. Therefore, in the embodiment, the shielding electrode 141 is arranged on at least one of the first sub-section 1211, the second sub-section 1212 or the third sub-section 1213, and the erosion path of water vapor formed along the first direction X can be blocked, avoiding defective pixels on the display panel 100, to improve the reliability and the service life of the display panel 100. It should be noted that the shielding electrode 141 is arranged on at least one of the first sub-section 1211, the second sub-section 1212 or the third sub-section 1213, which refers that the shielding electrode 141 may be arranged on one of the three sub-sections, or on two of the three sub-sections, or on the three sub-sections, which is not limited in the present disclosure.

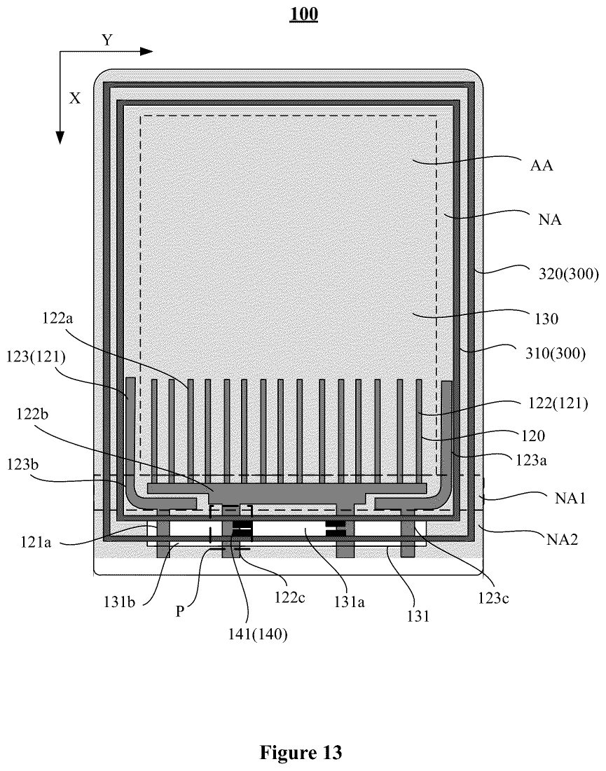

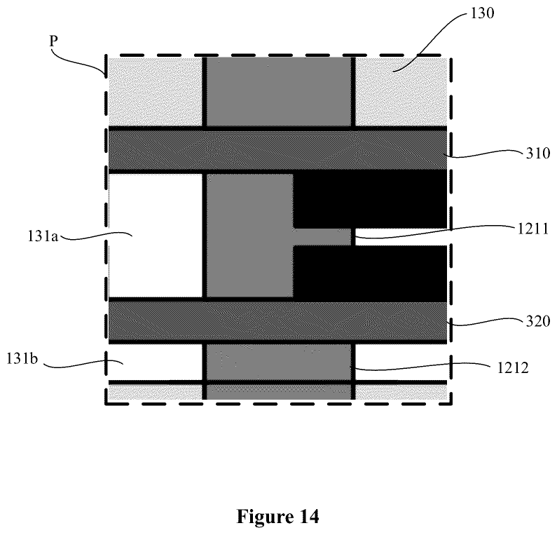

In another embodiment, as shown in FIG. 13 and FIG. 14, the opening 131 includes a first sub-opening 131a located between the first retaining wall 310 and the second retaining wall 320 and a second sub-opening 131b located on a side of the second retaining wall 320 away from the first retaining wall 310. The first section 121a includes the first sub-section 1211 located between the first retaining wall 310 and the second retaining wall 320 and the second sub-section 1212 located on the side of the second retaining wall 320 away from the first retaining wall 310. That is, in this embodiment, the opening 131 is divided into two sub-areas along the extension direction of the first section 121a, that is, the first direction X. Correspondingly, the first section 121a is divided into two sub-sections, that is, the first subsection 1211 and the second subsection 1212 except the part of the first section 121a covered by the first retaining wall 310 and the second retaining wall 320. In this way, the first sub-section 1211 and the second sub-section 1212 are exposed outside. Therefore, the shielding electrode 141 may be arranged on at least one of the first sub-section 1211 or the second sub-section 1212, and the erosion path of water vapor formed along the first direction X can be blocked, avoiding defective pixels on the display panel 100, to improve the reliability and service life of the display panel 100.

In some embodiments, as shown in FIG. 13, the signal wire 121 includes a first voltage signal wire 122. The first voltage signal wire 122 includes multiple first signal wires 122a located in the active area AA, a first main part 122b located in the fan-out area NA1 and at least one first connection part 122c extending from the fan-out area NA1 to the bonding area NA2. The first signal wires 122a, the first main part 122b and the first connection part 122c are electrical connected to each other. The first connection part 122c is configured to provide a first voltage signal for the first signal wires 122a. According to this embodiment, the specific structure of the first voltage signal wire 122 in the signal wire 121 is provided. As shown in FIG. 13, the first voltage signal wire 122 includes the multiple first signal wires 122a, the first main part 122b and the first connection part 122c. The first connection part 122c is connected to a driving chip to provide the first voltage signal for the sub-pixels of the active area AA through the first signal wires 122a. For example, the first voltage signal may be a PVDD voltage signal. It should be noted that FIG. 3, FIG. 11 and FIG. 13 only exemplarily illustrate a structure of a part of the first voltage signal wire 122 related to the shielding electrode 141, rather than the entire structure of the first voltage signal wire 122.

Further, the first section 121a includes at least one of the first main part 122b or the first connection part 122c. In an example shown in FIG. 13, since a position of the opening 131 does not overlap with a position of the first main part 122b but overlaps with a position of the first connection part 122c, the first section 121a includes the first connection part 122c of the first voltage signal wire 122. It can be understood that, a part of the first voltage signal wire 122 included in the first section 121a varies with a relative positional relationship between the opening 131 and the first voltage signal wire 122. For example, in some embodiments, if the position of the opening 131 overlaps with the position of the first main part 122b but does not overlap with the position of the first connection part 122c, the first section 121a includes the first main part 122b of the first voltage signal wire 122. The shielding electrode 141 is arranged on a surface and a side wall of the first main part 122b. For example, in some embodiments, if the position of the opening 131 overlaps with the position of the first main part 122b and also overlaps with the position of the first connection part 122c, the first section 121a includes the first main part 122b and the first connection part 122c of the first voltage signal wire 122. The shielding electrode 141 is arranged on both the surface and the side wall of the first main part 122b and a surface and a side wall of the first connection part 122c, which may be flexibly determined according to the actual situation.

In some embodiments, as shown in FIG. 13, a quantity of the at least one first connection part 122c is two, the two first connection parts 122c are spaced apart, and the first section 121a includes the two first connection parts 122c. In this embodiment, the two first connection parts 122c are spaced apart, to improve the convenience of the first connection part 122c connected to an external chip. Further, the first section 121a includes the first connection part 122c, that is, the opening 131 only exposes the first connection part 122c, and the shielding electrode 141 is arranged on the first connection part 122c, to improve the reliability and the service life of the display panel 100.

In some embodiments, referring to FIG. 4 and FIG. 13, the second metal layer 140 further includes the first electrode layer 151 arranged at the same layer as the shielding electrode 141. The first electrode layer 151 is located in the active area AA and electrically connected to the first signal wire 122a. In this embodiment, the second metal layer 140 includes the shielding electrode 141 and the first electrode layer 151, and the first electrode layer 151 may be the anode of the light-emitting unit 150. In other words, in the conventional technology, the second metal layer 140 is only for fabricating the first electrode layer 151 of the active area AA. In this embodiment, as the first electrode layer 151 is fabricated, the second metal layer 140 is formed as the shielding electrode 141 in the opening 131. In this way, the shielding electrode 141 is formed by using the existing metal layer without additionally arranging a metal layer, which is beneficial to saving process and reducing fabrication cost of the display panel 100, and reducing the thickness of the display panel 100.

In some embodiments, as shown in FIG. 13, the signal wire 121 further includes a second voltage signal wire 123. The second voltage signal wire 123 includes a second signal wire 123a surrounding at least a part of the active area AA, a second main part 123b located in the fan-out area NA1, and a second connection part 123c extending from the fan-out area NA1 to the bonding area NA2. The second signal wire 123a, the second main part 123b and the second connection part 123c are electrically connected to each other. The second connection part 123c is configured to provide a second voltage signal for the second signal wire 123a. According to this embodiment, a specific structure of the second voltage signal wire 123 in the signal wire 121 is provided. In this way, the second voltage signal can be provided to the sub-pixels by the second voltage signal wire 123. For example, the second voltage signal may be a PVEE voltage signal. It should be noted that, FIG. 3, FIG. 11 and FIG. 13 only exemplarily illustrate a structure of a part of the second voltage signal wire 123 related to the shielding electrode 141, rather than the entire structure of the second voltage signal wire 123.

Further, the first section 121a further includes at least one of the second main part 123b or the second connection part 123c. That is, a part of the second voltage signal wire 123 included in the first section 121a varies with a relative positional relationship between the opening 131 and the second voltage signal wire 123. That is, the first section 121a may include the second main part 123b. In one embodiment, the first section 121a may include the second connection part 123c. In one embodiment, the first section 121a includes the second main part 123b and the second connection part 123c. In this way, the shielding electrode 141 can be flexibly set according to the actual situation of the section 121a.

In some embodiments, as shown in FIG. 5, the first metal layer 120 includes a titanium layer 21a, an aluminum layer 21b and a titanium layer 21c that are stacked, which is beneficial to reducing the impedance of the signal wire 121 and improving the electrical conductivity of the signal wire 121.

A display device is provided according to an embodiment of the present disclosure, and includes the display panel 100 described in the embodiments. The display device according to the embodiment of the present disclosure includes the display panel 100 described in the first part, to improve the reliability and the service life of the display device. The display device may be a mobile phone, a computer monitor, a tablet computer or other electronic product, which is not limited in the present disclosure, as long as the display device is an electronic product with a display function.

In summary, in the display panel and the display device according to the embodiments of the present disclosure, the first metal layer is arranged on the side of the substrate and includes the signal wire, and the first section of the signal wire is located in the opening, and the first section is exposed outside. Further, the display panel according to the embodiment of the present disclosure is further provided with the second metal layer, the projection of the shielding electrode of the second metal layer on the substrate overlaps at least partially with the projection of the side wall of the first section on the substrate, and the shielding electrode can shield the side wall of the first section located in the opening. When an etching process is performed, the side wall of the first section shielded by the shielding electrode is not formed as the internal groove structure, and no organic material remains. In this way, along the direction of the bonding area to the fan-out area, at least part of the side wall of the first section does not include the organic material, and the erosion path of water vapor is blocked, avoiding defective pixels on the display panel, to improve the reliability and service life of the display panel.

Embodiments may be combined randomly. For conciseness of description, not all possible combinations of the features of the foregoing embodiments are described. However, as long as there is no contradiction in the combinations of these features, the combinations shall fall within the scope of this specification.

The foregoing embodiments only describes several implementations of the present disclosure. Although the description of the implementations is relatively specific and detailed, but not be construed as limitations to the scope of the present disclosure. Several modifications and improvements can be made, and these modifications and improvements fall within the protection scope of the present disclosure. Therefore, the protection scope of the present disclosure is subject to the claims.

1. A display panel, wherein at least a part of a border area of the display panel surrounds an active area of the display panel, the border area comprises a fan-out area located on a side of the active area and a bonding area located on a side of the fan-out area away from the active area, wherein the display panel comprises:
a substrate;
a first metal layer, arranged on a side of the substrate and comprising a signal wire;
an organic layer, arranged on a side of the first metal layer away from the substrate and comprising an opening defined in the border area, wherein the signal wire comprises a first section located in the opening; and
a second metal layer, comprising a shielding electrode arranged on the first section, wherein a projection of the shielding electrode on the substrate overlaps at least partially with a projection of a side wall of the first section on the substrate.

2. The display panel according to claim 1, wherein the first section extends along a first direction, the shielding electrode extends along a second direction, the first direction is a direction from the fan-out area to the bonding area, and the second direction is not parallel with the first direction.

3. The display panel according to claim 2, wherein the shielding electrode comprises at least one electrode block.

4. The display panel according to claim 2, wherein the shielding electrode comprises a plurality of metal wires arranged in parallel.

5. The display panel according to claim 2, wherein the first direction is perpendicular to the second direction.

6. The display panel according to claim 3, wherein the first direction is perpendicular to the second direction.

7. The display panel according to claim 4, wherein the first direction is perpendicular to the second direction.

8. The display panel according to claim 1, wherein the shielding electrode comprises a metal wire zigzagging in a length direction of the first section.

9. The display panel according to claim 1, further comprising a retaining wall structure arranged on the first metal layer,
wherein the retaining wall structure is arranged in the border area and surrounds the active area, and a projection of the first section on the substrate overlaps partially with a projection of the retaining wall structure on the substrate.

10. The display panel according to claim 9, wherein
the retaining wall structure comprises a first retaining wall and a second retaining wall;
the second retaining wall is arranged on a side of the first retaining wall away from the active area; and
at least a part of an orthographic projection of the opening on the substrate is located between the first retaining wall and the second retaining wall.

11. The display panel according to claim 10, wherein
the first section comprises a first sub-section located on a side of the first retaining wall away from the second retaining wall, a second sub-section located between the first retaining wall and the second retaining wall, and a third sub-section located on a side of the second retaining wall away from the first retaining wall; and
the shielding electrode is arranged on at least one of the first sub-section, the second sub-section, or the third sub-section.

12. The display panel according to claim 1, wherein the signal wire comprises a first voltage signal wire,
the first voltage signal wire comprises a plurality of first signal wires located in the active area, a first main part located in the fan-out area and at least one first connection part extending from the fan-out area to the bonding area;
the plurality of first signal wires, the first main part and the at least one first connection part are electrically connected to each other;
the at least one first connection part is configured to provide a first voltage signal for the plurality of first signal wires; and
the first section comprises at least one of the first main part or the first connection part.

13. The display panel according to claim 12, wherein a quantity of the at least one first connection part is two, the two first connection parts are spaced apart, and the first section comprises the two first connection parts.

14. The display panel according to claim 12, wherein the second metal layer further comprises a first electrode layer, and the first electrode layer is located in the active area and electrically connected to the plurality of first signal wires.

15. The display panel according to claim 12, wherein the signal wire further comprises a second voltage signal wire,
wherein the second voltage signal wire comprises a second signal wire surrounding at least a part of the active area, a second main part located in the fan-out area and a second connection part extending from the fan-out area to the bonding area;
the second signal wire, the second main part and the second connection part are electrically connected to each other; and
the first section further comprises at least one of the second main part or the second connection part.

16. The display panel according to claim 1, wherein the first metal layer comprises a titanium layer, an aluminum layer and a titanium layer that are stacked.

17. A display device, comprising a display panel, wherein at least a part of a border area of the display panel surrounds an active area of the display panel, the border area comprises a fan-out area located on a side of the active area and a bonding area located on a side of the fan-out area away from the active area, wherein the display panel comprises:
a substrate;
a first metal layer, arranged on a side of the substrate and comprising a signal wire;
an organic layer, arranged on a side of the first metal layer away from the substrate and comprising an opening defined in the border area, wherein the signal wire comprises a first section located in the opening; and
a second metal layer, comprising a shielding electrode arranged on the first section, wherein a projection of the shielding electrode on the substrate overlaps at least partially with a projection of a side wall of the first section on the substrate.
